(19) United States
(12) Patent Application Publication
(10) Pub. No.: US 2007/0257343 A1
(43) Pub. Date: Nov. 8, 2007

(54) DIE-ON-LEADFRAME (DOL) WITH HIGH VOLTAGE ISOLATION

(76) Inventors: Henning M. Hauenstein, Redondo Beach, CA (US); Jack Marcinkowski, San Pedro, CA (US); Heny Lin, Irvine, CA (US)

Correspondence Address: OSTROLENK FABER GERB & SOFFEN, 1180 AVENUE OF THE AMERICAS, NEW YORK, NY, 100368403, US

(21) Appl. No.: 11/743,737

(22) Filed: May 3, 2007

Related U.S. Application Data
(60) Provisional application No. 60/798,260, filed on May 5, 2006.

(51) Int. Cl. H01L 23/495; H01L 23/24; H01L 23/48; H01L 23/52

(52) U.S. Cl. 257/676; 257/690; 257/687; 257/784

(57) ABSTRACT

A high voltage semiconductor module has a leadframe with spaced pads which is connected to a heat sink plate by a curable insulation layer on the top of the plate. Semiconductor die may be soldered to the leadframe pads before or after assembly to the plate. The insulation layer may be a curable epoxy or a B stage IMS plate.

### RELATED APPLICATIONS

This application claims the benefit of U.S. Provisional Application No. 60/798,260, filed May 5, 2006, the entire disclosure of which is incorporated by reference herein.

### FIELD OF THE INVENTION

This invention relates to semiconductor device modules and to a process for their manufacture.

### BACKGROUND OF THE INVENTION

There in an increasing demand for the management of high currents in a very small space and in harsh environments exposed to large temperature changes during device lifetime. Thus, in the automotive sector there is an increasing electrification of functions and the current demand increases enormously due to the use of inverter and e-motor drives for hybrid car applications, starter-generator applications, high power DC/DC converter or x-by-wire applications such as electric power steering or electric braking. These applications need high current carrying devices of minimum volume, challenging the state-of-the-art power modules in terms of achievable power density.

Beyond these technical requirements a low-cost approach is essential.

The power and current carrying capabilities of power switches like MOSFET and IGBT die (which may be of silicon or GaN or other semiconductor material) is often limited by the package. The package introduces thermal and electrical resistance that can cause power loss and corresponding heating of the semiconductor devices beyond the die limits.

In order to achieve high power densities it is common to mount bare die on a substrate that provides an electric interconnection which normally is provided by a structured metal layer like the patterned Cu-layer of a DBC (direct bonded copper) wafer; a structured Cu-layer on an IMS (insulated metal substrate) or a structured leadframe employing “Die-on-Leadframe” (DOL) technology. Such DOL structures are shown in U.S. Pat. No. 6,703,703, issued May 9, 2004 entitled LOW COST POWER SEMICONDUCTOR WITHOUT SUBSTRATE in the name of William Grant, the subject matter of which is incorporated herein by reference.

For better reliability many applications use DBC as a substrate material for the following main reasons:

The thermal expansion coefficient of DBC matches that of the Si die soldered thereto relatively well, offering a stress reduced package (especially useful for high temperature cycling application).

The ceramic layer of the DBC provides high electric isolation between the top and the bottom-Cu-layer (typically in the kV range).

Due to the electric isolation capability of the ceramic base, it is possible to mount the DBC on a heat-sink (with active/forced cooling or passive/air cooling if desired) which provides a good thermal management in high power applications, especially for power modules.

Disadvantages of the DBC (or IMS) include high cost, since the application specific layout requires the whole DBC or IMS to be customized. Further, the high thermal resistance of the relatively thick ceramic of the DBC is a serious drawback. Moreover, neither DBC nor IMS allow thick Cu-layers due to the mechanical stress introduced between the Cu and the isolation layer. (Typical available Cu-layer dimensions in DBC and IMS are about 100 μm to about 300 μm.)

Therefore, it would be more advantageous to solder the bare die onto a relatively thick Cu-block (e.g. a thickness of about 1 mm or greater) which produces thermal spreading of the heat generated within the Semiconductor material die.

The die-on-leadframe (DOL) technology referred to above addresses this issue and takes advantage of bare die soldered directly to a relatively thick Cu-leadframe. Though the thermal mismatch between a metal leadframe and a Si-die can be quite significant; many applications can use this more cost effective and thermally advantageous technology without reliability issues.

One disadvantage of the known die-on-leadframe (DOL) technology is the missing electric isolation. Thus, the metal leadframe does not provide any electric isolation to the bottom or backside of a corresponding module since the leadframe is in direct contact with the semiconductor die. Therefore, a die-on-leadframe system cannot be directly mounted on a heat-sink or a mounting-plate in an application (as on a motor end-shield) since it would connect those elements to the electric system.

This missing isolation is especially critical if the application requires or provides a liquid cooled heat-sink which is very beneficial for the thermal management of the power module. But a liquid cooled heat-sink needs to be safely isolated from the electric potential of the leadframe. This problem exists in particular in automotive systems using high-voltage batteries with voltages in excess of about 40 volts as in hybrid electric cars.

Thus, the die-on-leadframe (DOL) assembly is mounted on a heat-sink mainly in low voltage applications where a relatively well controlled thin adhesive layer is provided underneath the leadframe in order to ensure the isolation without seriously blocking heat transfer.

This adhesive layer, however, does disturb the thermal advantage of the leadframe since even thin adhesives have a relatively low thermal conductivity. However, in order to ensure voltage isolation, the adhesive needs to have a certain minimum thickness. Further, the non-flatness of the DOL module (like the leadframe) also makes it very difficult to achieve a minimum thickness homogeneous adhesive layer for voltage isolation purposes.

A thickness controlled adhesive layer can be provided by distance control elements such as bumps or by mounting the leadframe into a supporting plastic shell. However, these solutions are still limited to low voltage applications. This solution could also be disadvantageous in terms of cost, space requirements, manufacturability, and reliability.

It would be very desirable to provide a cost effective high voltage die-on-leadframe (DOL) power module which is high in thermal performance and which provides good voltage isolation.

### SUMMARY OF THE INVENTION

In accordance with the invention, a die on leadframe subassembly is fixed to and insulated from a conductive plate by a curable insulation layer on the conductive plate. In a preferred embodiment, the invention improves the voltage isolation of an existing die-on-leadframe assembly by employing a B-stage IMS structure underneath the leadframe/DOL module. A B-stage IMS structure is the IMS structure before the connection of the top Cu layer to the base plate. Thus, the leadframe of the DOL module is employed in place of the top copper layer, of conventional IMS and the curable insulation layer is cured to fix the DOL leadframe in place. The insulation layer is electrically insulative, but has good thermal conductivity.

### ADVANTAGES OF THE INVENTION

The Invention Offers

a) Improved mechanical properties:
i) Connection of the thermally conductive isolation layer and the leadframe is done by a reliable and rugged bond process by applying temperature and pressure (no large solder or adhesive areas are required).
ii) Homogeneous isolation layer is provided with a well defined thickness.
iii) Reduced tolerance on flatness requirements on leadframe/DOL modules.
iv) Application-flexibility since customization is done on the leadframe and by customizing the external interfaces such as power and signal terminals. The main die-on-leadframe module forms a sub-platform which is easily adapted to a customer or users.

Due to the above described high flexibility of use and due to different available options the new module will cover a broad bandwidth of power module applications in the power management market.

A main application field will be for modules that can switch high currents or high voltages, like inverters, motor-drives and DC/DC converter applications in the automotive sector.

Generally, the invention can be used in any high power density application using MOSgated devices such as MOSFETs an IGBTs or other semiconductor die and applications in harsh environmental conditions or difficult temperature cycling requirements as in automotive or safety-critical functions with a demand for high reliability.

### BRIEF DESCRIPTION OF THE DRAWINGS

FIG. 1 is a cross-section of a known insulated metal substrate (IMS).

FIG. 2 shows the IMS of FIG. 1 before the application of the top copper layer, with the structure in the form of “B-stage IMS.”

FIG. 3 shows a schematic cross-section of a die-on-leadframe assembly.

FIG. 4 shows the combination of a die on leadframe sub-assembly fixed to a B-stage IMS in accordance with one embodiment of the invention.

### DETAILED DESCRIPTION OF THE PREFERRED EMBODIMENT

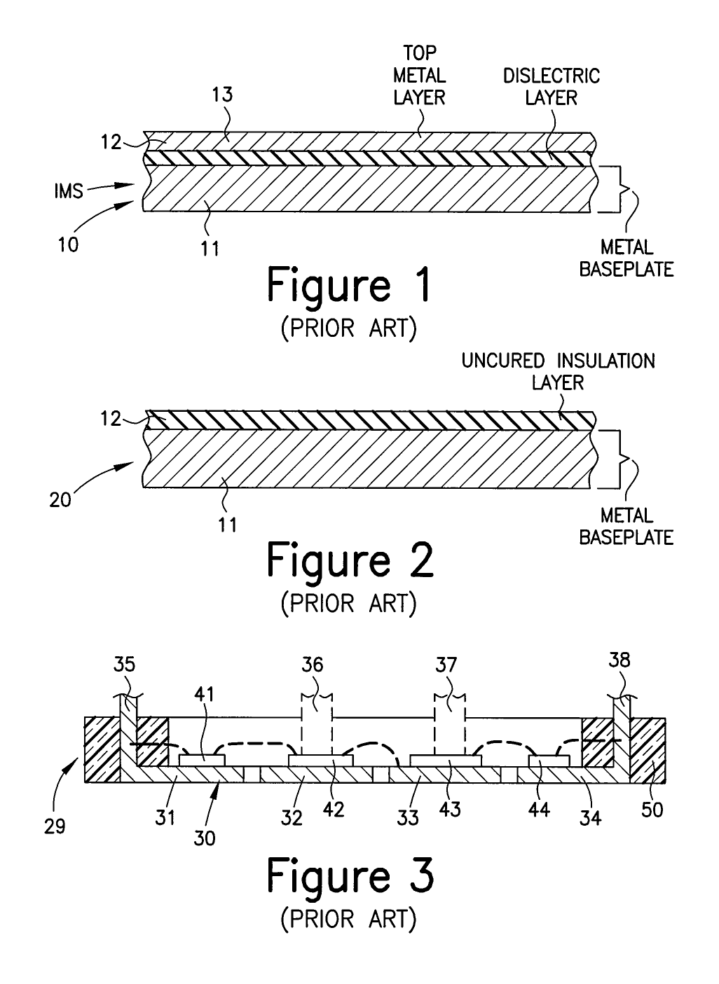

FIG. 1 shows a typical IMS substrate 10 which consists of a planar metal base plate 11 which may be of copper or aluminum of thickness of typically 0.5 to 3.0 mm. An electrically insulative but thermally conductive, curable dielectric material 12 is fixed or applied to the top of base plate 11 and has a thickness, typically of 100 to 250 μm. A conductive copper layer 13 which has a thickness up to about 300 μm is fixed to the curable layer 12. The curable layer 12 is cured to fix layer 13 to base plate 11 by the application of suitable temperatures and/or pressures. Such products are commercially available, one source being the DENKA Corporation.

This product permits the controlled patterning of copper layer 13 to create insulated semiconductor die pads and interconnecting circuit pathways to form electrical circuits with such semiconductor die and with passive electrical components which may also be mounted on the IMS substrate. Further, there is excellent heat transfer through insulation coating 12 to base plate 11 and cured dielectric 12 provides good high voltage electrical isolation between the patterned copper layer 13 and the baseplate 11. However, as stated previously, the copper layer 13 is very thin (up to 300 μm), and the thickness of the IMS layers of FIG. 1 have to be tailor-made to the particular application of the structure.

The IMS substrate of FIG. 1 is also has a so-called B-stage IMS 20 state before layer 13 is applied, as shown in FIG. 2, consisting of the baseplate 11 and the dielectric layer 12 (uncured). As will be later seen, a die on leadframe subassembly can have its bottom leadframe surface bonded to baseplate 11 (in place of layer 13 of FIG. 1) by curing film 12 of the B-stage IMS 20.

FIG. 3 schematically shows a typical die on leadframe (DOL) subassembly 29 of the type shown in U.S. Pat. No. 6,703,703. Thus, a flat, relatively thick copper sheet or other metal leadframe 30 is stamped and patterned to have, for example, die receiving pads 31, 32, 33, 34. Portions of the leadframe may be upwardly turned to provide assembly terminals 35, 36, 37, 38, for example. Semiconductor die 41, 42, 43 and 44 are mounted on and soldered to pads 31 to 34 respectively. A conductive adhesive could also be used. Die 31 to 34 may be MOSgated devices such as MOSFETs, IGBTs and the like or other semiconductor die. Further, other pads or areas, not shown, may carry diodes or passive components needed to form the desired circuit to be contained in the DOL subassembly 29.

An insulation frame 50 which may be an insulation plastic or ceramic or any other insulation material then is fixed as shown around the leadframe body.

In use, the subassembly 29 is mounted on a suitable mount at the bottom surface of leadframe 3, but must be electrically insulated from such a mount if it is conductive. This is frequently difficult and can reduce the efficiency of the DOL circuits in such an application. Further, it would be difficult to use fluid cooling with such an assembly.

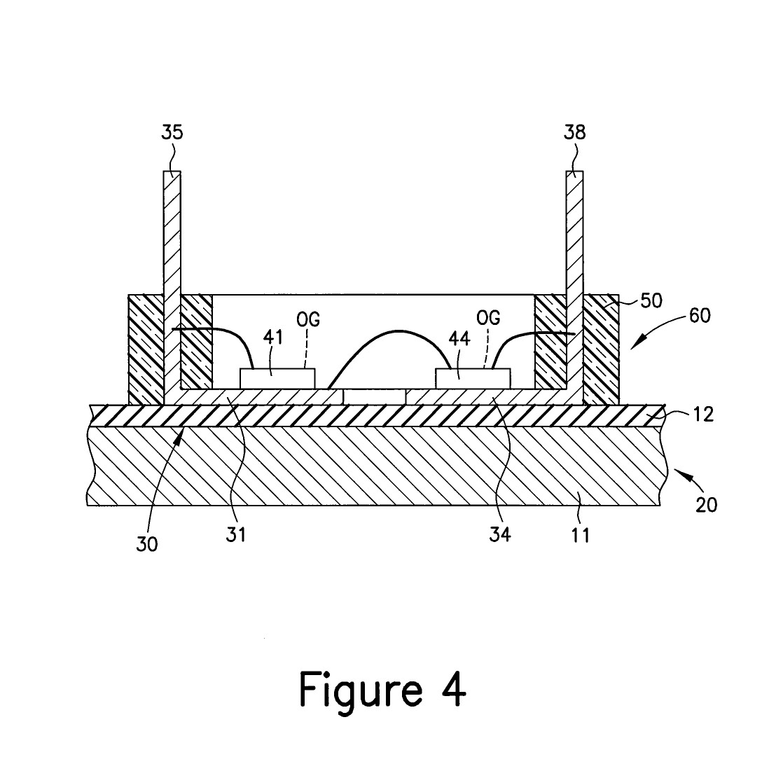

FIG. 4 shows a preferred embodiment of the invention in which a DOL assembly 60, which is similar to DOL assembly 29, and in which similar components have the same reference number, has the bottom of leadframe 30 fixed to base plate 11 by the curing of dielectric layer 12 by the use of the conventional temperature and/or pressure process used to secure copper layer 13 to the base plate 11 in FIG. 1.

In another embodiment of the invention, the B-stage IMS can be replaced by a metal base plate having a curable epoxy layer on its top surface. The epoxy will preferable be filled with small ceramic spheres to permit the bottom of leadframe to be spaced by a gap of predetermined thickness, for example, 100 to 250 μm. Alternatively, the techniques disclosed in copending application Ser. No. 11/619,742, filed Jan. 4, 2007, entitled SUBSTRATE AND METHOD FOR MOUNTING SILICON DEVICE in the name of Henning Hauenstein (IR-3178), the full contents of which are incorporated herein by reference, may be used.

In still another embodiment of the invention, the die 41, 44 and the wire bonds for their interconnection may be made after the patterned leadframe is secured to the base plate 11 through the B-stage dielectric 12 or another thin epoxy coating.

The novel structure of FIG. 4 and its alternatives above has the following benefits:

a) Improved electrical and thermal properties:
i) Optimized heat-spreading out of the die 41, 44 into the thick leadframe 30 before the heat wave enters the less thermally conductive adhesive 12.
ii) High Voltage Electric isolation (well defined over isolation layer 12 thickness).
iii) Optimization between electric isolation (a thicker layer 12) and thermal resistance (a thinner layer 12) can be selected according to application needs.
iv) Mountability on a heat-sink (even liquid/active cooled) provides further cooling power.
v) Increased current/power capability due to low thermal resistance.

b) Improved manufacturing and handling properties:
i) Leadframe 30 can be customized and changed independently from the B-stage IMS 20 which can be produced as a standard/platform part in large volume;
ii) Die 41, 44 are more easily soldered to the leadframe before mounting the leadframe 30 on the B-stage IMS 20 and the leadframe doesn't need to be moved through the module manufacturing line. That is, e.g. soldering of the die to the pure leadframe 30 is easier then heating up a complete isolated substrate 11 with isolation layer 12 since the bottom part of the pure leadframe 30 has less heat capacity and a better thermal contact to the solder oven.
iii) The DOL modules 29 or 60 are fully tested prior to mounting on a B-stage IMS plate 20.

c) Low manufacturing and test costs due to:
i) Cost effective large volume production of B-stage IMS 20 is possible since no customization is necessary on this element. Customization is done on the leadframe 29, 60 only, which will be attached to the B-stage IMS 20.
ii) Design and layout changes only have an influence on the leadframe 30 and not on the B-stage IMS part 20.
iii) Since the DOL module 29, 60 is a fully tested part prior the mounting to IMS 20, a high end of line yield can be achieved.
iv) Cost optimized module can be produced with the electric isolation as an option. Thus, standard modules can be developed which can be equipped with the electric isolation (B-stage IMS) after finishing the electric assembly leading to volume bundling, manufacturing standardization and production line sharing (reduced tooling and equipment costs).

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. A semiconductor device module comprising a flat conductive leadframe having at least two spaced insulated pad segments and having flat parallel upper and lower surfaces; at least first and second semiconductor die each having top and bottom surfaces and having their said bottom surfaces electrically and mechanically secured atop the top surfaces of respective ones of said first and second pads; said at least first and second die connected in a predetermined circuit relation with one another and having output terminals for connection to exterior circuits; an insulated conductive support for receiving the bottom of said flat conductive leadframe; said insulated conductive support comprising a conductive body having a flat upper surface and a curable insulation layer atop said flat upper surface; said bottom surface of said leadframe mechanically secured to said top surface of said curable insulation layer by the curing of said layer, and insulated from said conductive body by said insulation layer.

2. The module of claim 1, wherein said semiconductor die are MOSgated devices.

3. The module of claim 1, wherein said conductive body is a flat metallic plate.

4. The module of claim 1, wherein said module is a high voltage module in which the voltage between said output terminals is in excess of about 50 volts.

5. The module of claim 1, wherein said flat leadframe has upstanding projections extending away from said insulated conductive support and defining said terminals.

6. The module of claim 1, wherein said insulated conductive support is a B-stage IMS structure.

7. The module of claim 1, wherein said curable insulation layer is a ceramic particle-filled epoxy.

8. The module of claim 1, wherein said curable insulation layer has a thickness of about 100 to about 250 μm, and said conductive body is a flat metallic plate of thickness of about 0.5 to 3.0 mm.

9. The process for manufacture of a high voltage insulated semiconductor module comprising the steps of assembling semiconductor die on the insulated pads of a conductive leadframe and connecting said die into a predetermined circuit, and thereafter placing the bottom of said leadframe atop the insulation surface of a B-stage IMS plate, and thereafter curing said insulation layer of said B-stage IMS plate to fix said leadframe to said insulation surface of said IMS plate whereby said leadframe is insulated from the metal base plate of said B-stage IMS plate.

10. The process for manufacture of a high voltage insulated semiconductor module comprising the steps of assembling semiconductor die on the insulated pads of a conductive leadframe and connecting said die into a predetermined circuit, and thereafter placing the bottom of said leadframe atop a curable insulation coating atop a conductive plate and thereafter curing said curable insulation layer to mechanically fix said leadframe atop said conductive plate and to electrically insulate said leadframe from said plate.

11. The process of claim 10, wherein said curable insulation layer includes a curable epoxy.

12. The process of claim 10, wherein said plate and said curable insulation layer are components of a B-stage IMS plate.

13. The process for manufacture of a high voltage insulated semiconductor module comprising the steps of placing the bottom of said leadframe atop the insulation surface of a B-stage IMS plate, and thereafter curing said insulation layer of said B-stage IMS plate to fix said leadframe to said insulation surface of said IMS plate whereby said leadframe is insulated from the metal base plate of said B-stage IMS plate.

14. The process of claim 13, which further includes the step of mounting semiconductor die on at least selected pads of said leadframe after curing said curable insulation layer.

15. The process for manufacture of a high voltage insulated semiconductor module comprising the steps of placing the bottom of said leadframe atop a curable insulation coating atop a conductive plate and thereafter curing said curable insulation layer to mechanically fix said leadframe atop said conductive plate and to electrically insulate said leadframe from said plate and which further includes the step of mounting semiconductor die on at least selected pads of said leadframe after curing said curable insulation layer.

16. The process of claim 15, wherein said curable insulation layer includes a curable epoxy.

17. The process of claim 15, wherein said plate and said curable insulation layer are components of a B-stage IMS plate.
